(19) United States
(12) Patent Application Publication
(10) Pub. No.: US 2026/0136996 A1
(43) Pub. Date: May 14, 2026

(54) SEMICONDUCTOR PACKAGE

(71) Applicant: Samsung Electronics Co., Ltd., Suwon-si (KR)

(72) Inventors: Dongkuk Lee, Suwon-si (KR); Seungduk Baek, Suwon-si (KR)

(21) Appl. No.: 19/242,103

(22) Filed: Jun. 18, 2025

(30) Foreign Application Priority Data
Nov. 13, 2024 (KR) 10-2024-0160746

(51) Int. Cl. H01L 23/00; H01L 25/04

(52) U.S. Cl. CPC H10W 90/00; H10W 72/222; H10W 72/244; H10W 72/247; H10W 72/942; H10W 72/944; H10W 74/15; H10W 90/28; H10W 90/722; H10W 90/724; H10W 90/732

(57) ABSTRACT

A semiconductor package includes a first semiconductor chip having a first front surface and a first back surface opposing each other, and including first front connection pads, first back connection, and through-electrodes, a second semiconductor chip having a second front surface facing the first back surface and including second front connection pads, a substrate having a third back surface facing the first front surface and including upper pads and lower pads disposed opposite to each other, first bump structures between the first semiconductor chip and the second semiconductor, second bump structures between the first semiconductor chip and the substrate, and connection bumps. A first gap between the second front surface and the first back surface is equal to or greater than a second gap between the first front surface and the third back surface, and the second gap is greater than a thickness of the first semiconductor chip.

### CROSS-REFERENCE TO RELATED APPLICATION(S)

This application claims the benefit under 35 USC 119(a) of Korean Patent Application No. 10-2024-0160746 filed on Nov. 13, 2024 in the Korean Intellectual Property Office, the entire disclosure of which is incorporated herein by reference for all purposes.

### BACKGROUND

As electronic devices become lighter and more powerful, semiconductor packages are desired to be miniaturized with high-performance. To implement miniaturization, lightness, high performance, and high reliability of semiconductor packages, semiconductor packages having stacked semiconductor chips are being researched and developed.

### SUMMARY

The present disclosure provides a semiconductor package having improved reliability and various advantages discussed herein.

According to example implementations, a semiconductor package includes a first semiconductor chip having a first front surface and a first back surface opposing each other, and including first front connection pads on the first front surface, first back connection pads adjacent to each other on the first back surface, and through-electrodes electrically connecting at least a portion of the first front connection pads to at least a portion of the first back connection pads; a second semiconductor chip having a second front surface facing the first back surface and including second front connection pads on the second front surface; a substrate having a third back surface facing the first front surface and including upper pads and lower pads opposite to each other; first bump structures between the first semiconductor chip and the second semiconductor chip and electrically connecting the first back connection pads and the second front connection pads; second bump structures between the first semiconductor chip and the substrate and electrically connecting the upper pads of the substrate and the first front connection pads of the first semiconductor chip; and connection bumps below the substrate. A first gap between the second front surface and the first back surface is equal to or greater than a second gap between the first front surface and the third back surface, and the second gap is greater than a thickness of the first semiconductor chip.

According to example implementations, a semiconductor package includes a first semiconductor chip having a first front surface and a first back surface opposing each other, and including first front connection pads on the first front surface, first back connection pads adjacent to each other on the first back surface, and through-electrodes electrically connecting at least a portion of the first front connection pads to at least a portion of the first back connection pads; a second semiconductor chip having a second front surface facing the first back surface and including second front connection pads on the second front surface; a substrate having a third back surface facing the first front surface and including upper pads and lower pads opposite to each other; first bump structures between the first semiconductor chip and the second semiconductor chip and electrically connecting the first back connection pads and the second front connection pads; second bump structures between the first semiconductor chip and the substrate and electrically connecting the upper pads of the substrate and the first front connection pads of the first semiconductor chip; and connection bumps below the substrate. A thickness of the first semiconductor chip is in a range of about 10 μm to about 60 μm, and a first gap between the second front surface and the first back surface is equal to or greater than a second gap between the first front surface and the third back surface.

According to example implementations, a semiconductor package includes a first semiconductor chip having a first front surface and a first back surface opposing each other, and including first front connection pads on the first front surface, first back connection pads adjacent to each other on the first back surface, and through-electrodes electrically connecting at least a portion of the first front connection pads to at least a portion of the first back connection pads; a second semiconductor chip having a second front surface facing the first back surface, and including second front connection pads on the second front surface; a substrate having a third back surface facing the first front surface, and including upper pads and lower pads opposite to each other; first bump structures between the first semiconductor chip and the second semiconductor chip, and electrically connecting the first back connection pads and the second front connection pads; second bump structures between the first semiconductor chip and the substrate, and electrically connecting the upper pads of the substrate and the first front connection pads of the first semiconductor chip; connection bumps below the substrate; an adhesive film surrounding the first back connection pads and a portion of each of the first bump structures, between the first semiconductor chip and the second semiconductor chip; and an encapsulation layer on the first semiconductor chip and surrounding a side surface of the adhesive film and a side surface of the second semiconductor chip. A vertical length of a contact surface between the encapsulation layer and the adhesive film is equal to or greater than a second gap between the first front surface and the third back surface, and the second gap is greater than a thickness of the first semiconductor chip.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a cross-sectional view illustrating a semiconductor package according to an example implementation, FIG. 1B is a partial enlarged view illustrating area ‘A’ of FIG. 1A, and FIG. 1C is a bottom view illustrating a front surface of an example of one of stacked semiconductor chips of FIG. 1A;

FIG. 2A is a cross-sectional view illustrating a semiconductor package according to an example implementation, and FIG. 2B is a partial enlarged view illustrating area ‘B’ of FIG. 2A;

FIG. 3 is a cross-sectional view illustrating a semiconductor package according to an example implementation;

FIG. 4 is a cross-sectional view illustrating a semiconductor package according to an example implementation;

FIG. 5A is a perspective view schematically illustrating a semiconductor package according to an example implementation, and FIG. 5B is a cross-sectional view illustrating a cross-section along line III-III′ of FIG. 5A;

FIG. 6A is a perspective view schematically illustrating a semiconductor package according to an example implementation, and FIG. 6B is a cross-sectional view illustrating a cross-section along II-II′ of FIG. 6A; and

FIGS. 7A to 7H are cross-sectional views schematically illustrating a process of manufacturing a semiconductor package according to an example implementation.

### DETAILED DESCRIPTION

Hereinafter, example implementations will be described with reference to the accompanying drawings.

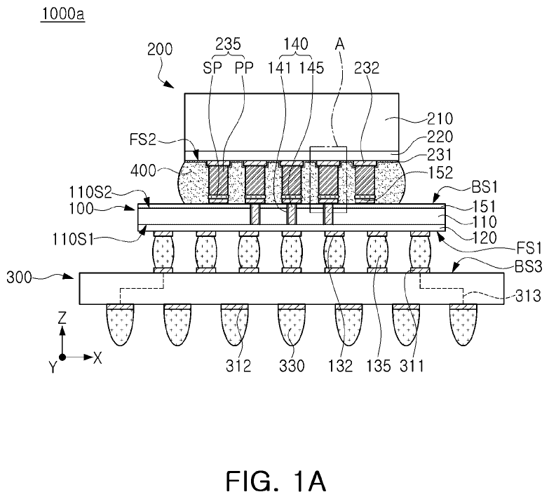

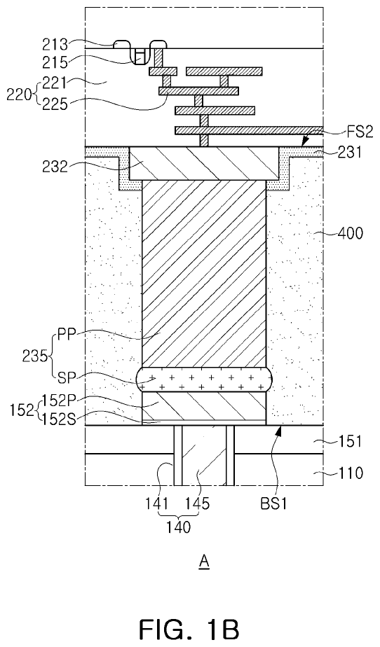

FIG. 1A is a cross-sectional view illustrating a semiconductor package 1000a according to an example implementation, FIG. 1B is a partial enlarged view illustrating area ‘A’ of FIG. 1A, and FIG. 1C is a bottom view illustrating the front of a second semiconductor chip 200 of FIG. 1A.

Referring to FIGS. 1A to 1C, a semiconductor package 1000a according to an example implementation may include a plurality of semiconductor chips (including semiconductor chips 100 and 200) stacked in a vertical direction (Z direction), bump structures 235 electrically connecting the plurality of semiconductor chips 100 and 200, and an adhesive film 400 fixing and supporting the plurality of semiconductor chips 100 and 200. For example, the semiconductor package 1000a may include a first semiconductor chip 100 and a second semiconductor chip 200 stacked on the first semiconductor chip 100, but the number of semiconductor chips to be stacked is not limited thereto.

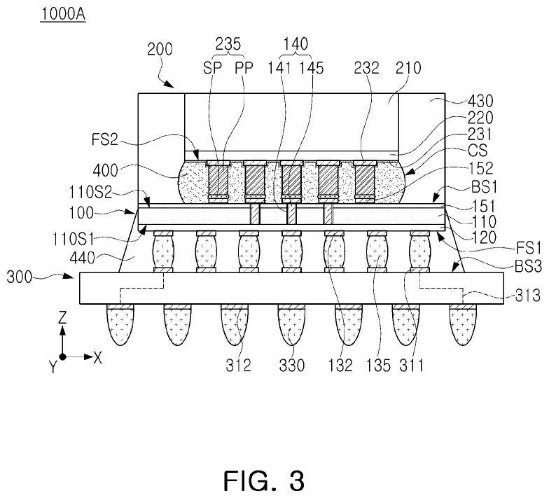

In example implementations of the present disclosure, deformation of the semiconductor package may be reduced and cracks may be prevented by increasing the size of the bump structures 235 between the first semiconductor chip 100 and the second semiconductor chip 200 to increase the volume of an encapsulating material when the first semiconductor chip is ultra-thin. For example, the encapsulating material may include the adhesive film 400 and the plurality of encapsulation layers 430 and 440 (see e.g., FIG. 3) in the present disclosure.

The bump structures 235 may be formed to have a predetermined position and height to increase the volume of the encapsulating material having a large coefficient of thermal expansion. For example, the gap (e.g., a vertical or stacking distance) between a second front surface FS2 and a first back surface BS1 of the semiconductor package 1000a may be equal to or greater than the gap between a first front surface FS1 and a third back surface BS3. The gap between the first front surface FS1 and the third back surface BS3 may be greater than the thickness of the first semiconductor chip 100. In some implementations, the thickness of the first semiconductor chip 100 may be in the range of, for example, about 10 μm to about 60 μm, but is not limited thereto.

The first semiconductor chip 100 may be formed in an ultra-thin shape. For example, the thickness of the first semiconductor chip 100 may be in the range of, for example, about 10 μm to about 60 μm, but is not limited thereto. The thickness of the second semiconductor chip 200 may be, for example, in the range of about 300 μm to about 750 μm, but is not limited thereto. In addition, the thickness ratio of the second semiconductor chip 200 to the first semiconductor chip 100 may be about 8.4 or more, but is not limited thereto.

The first semiconductor chip 100 may have the first front surface FS1 and the first back surface BS1 opposing each other, and may include a first substrate 110, a first circuit layer 120, through-electrodes 140, and a plurality of connection pads 132 and 152. The second semiconductor chip 200 may be disposed on the first back surface BS1 of the first semiconductor chip 100, and a plurality of connection bumps may be disposed on the first front surface FS1.

The first substrate 110 may include, for example, a semiconductor element such as silicon or germanium (Ge), or a compound semiconductor such as silicon carbide (SiC), gallium arsenide (GaAs), indium arsenide (InAs), or indium phosphide (InP). A first circuit layer 120 may be disposed on an active surface 110S1 of the first substrate 110, and a first back insulating layer 151 may be disposed on an inactive surface 110S2 of the first substrate 110.

Since the first circuit layer 120 and the first substrate 110 have the same or similar characteristics as a second circuit layer 220 and a second substrate 210 of the second semiconductor chip 200 described below, the detailed description of the first circuit layer 120 and the first substrate 110 is omitted for brevity purposes and instead references to the below description of the second circuit layer 220 and the second substrate 210 illustrated in FIG. 1A.

The first back insulating layer 151 may be disposed on the inactive surface 110S2 of the first substrate 110. The first back insulating layer 151 may be formed to surround the upper portion of the through-electrodes 140. The first back insulating layer 151 may electrically insulate the first back connection pads 152 from the semiconductor material forming the first substrate 110. The first back insulating layer 151 may include silicon oxide, silicon oxide nitride, silicon nitride, a polymer, or combinations thereof. The first back insulating layer 151 may be formed using a chemical vapor deposition (CVD), a flowable-CVD process, or a spin coating process.

The through-electrodes 140 may extend into the first substrate 110 and electrically connect at least a portion of the first front connection pads 132 and at least a portion of the first back connection pads 152. The through-electrodes 140 may include a via plug 145 and a side barrier film 141 surrounding a side surface of the via plug 145. The via plug 145 may include, for example, tungsten (W), titanium (Ti), aluminum (Al), or copper (Cu), and may be formed using a plating process, a PVD process, or a CVD process. The side barrier film 141 may include titanium (Ti), titanium nitride (TiN), tantalum (Ta), or tantalum nitride (TaN), and may be formed by a plating process, a PVD process, or a CVD process. A side insulating film including an insulating material (for example, High Aspect Ratio Process (HARP) oxide) such as silicon oxide, silicon nitride, or silicon oxynitride may be formed between the side barrier film 141 and the first substrate 110.

The plurality of connection pads 132 and 152 may include first front connection pads 132 disposed on the first front surface FS1, and first back connection pads 152 disposed on the first back surface BS1. The first front connection pads 132 and the first back connection pads 152 may include, for example, at least one of aluminum (Al), copper (Cu), nickel (Ni), tungsten (W), platinum (Pt), and gold (Au).

The first back connection pads 152 may be connected to integrated circuits or individual components in the first circuit layer 120 through through-electrodes 140, or may be connected to the first front connection pads 132. The first front connection pads 132 and the first back connection pads 152 may include signal pads, power pads, and ground pads.

Referring to FIG. 1B, the first back connection pads 152 may include a seed layer 152S disposed on the first back surface BS1 and a plating layer 152P disposed on the seed layer 152S. Similarly, the first front connection pads 132 and second front connection pads 232 may include a seed layer.

A plurality of connection bumps 135 are disposed between the first semiconductor chip 100 and the package substrate 300 and may electrically connect the first front connection pads 132 and the upper pad 311 facing each other. The plurality of connection bumps 135 may include, for example, tin (Sn) or an alloy (for example, Sn—Ag—Cu) including tin (Sn). According to an example implementation, the plurality of connection bumps 135 may have a form in which a metal pillar and a solder ball are combined.

The second semiconductor chip 200 may have the second front surface FS2 facing the first front surface FS1 of the first semiconductor chip 100, and may include a second substrate 210, a second circuit layer 220, and the second front connection pads 232. According to an example implementation, the second semiconductor chip 200 may further include a protective layer 231 covering the second front surface.

The second substrate 210 may include a semiconductor material similar to that of the first substrate 110. The second substrate 210 may have a Silicon On Insulator (SOI) structure. Referring to FIG. 1B, the second substrate 210 may include a conductive region 213, for example, a well doped with impurities, a structure doped with impurities, and various device isolation structures such as a Shallow Trench Isolation (STI) structure. Individual elements 215 constituting an integrated circuit may be disposed on an active surface of the second substrate 210 on which the conductive region 213 is formed. The conductive region 213 and the individual elements 215 may be electrically connected to the second front connection pads 232 through a wiring structure 225. The individual elements 215 may include various active elements and/or passive elements such as Field Effect Transistors (FETs) such as planar FETs or FinFETs, memory elements such as flash memory, Dynamic Random Access Memory (DRAMs), Static Random Access Memory (SRAMs), Electrically Erasable Programmable Read-Only Memory (EEPROMs), Phase-change Random Access Memory (PRAMs), Magnetoresistive Random Access Memory (MRAMs), Ferroelectric Random Access Memory (FeRAMs), and Resistive Random Access Memory (RRAMs), logic elements such as ANDs, ORs, and NOTs, and system Large Scale Integration (LSIs), CMOS Imaging Sensors (CISs), and Micro-Electro-Mechanical Systems (MEMSs).

Referring to FIG. 1B, the second circuit layer 220 may be disposed on the active surface of the second substrate 210 and may include an interlayer insulating layer 221 and a wiring structure 225. The interlayer insulating layer 221 may include Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or combinations thereof. At least a portion of the interlayer insulating layer 221 surrounding the wiring structure 225 may be formed of a low-k dielectric layer. The interlayer insulating layer 221 may be formed using a chemical vapor deposition (CVD), a flowable-CVD process, or a spin coating process.

The wiring structure 225 may be disposed between the second substrate 210 and the second front connection pads 232, and may be embedded in the interlayer insulating layer 221. The wiring structure 225 may be formed as a multilayer structure including a wiring pattern and vias formed of, for example, aluminum (Al), gold (Au), cobalt (Co), copper (Cu), nickel (Ni), lead (Pb), tantalum (Ta), tellurium (Te), titanium (Ti), tungsten (W), or a combination thereof. Between the wiring pattern or/and the via and the interlayer insulating layer 221, a barrier film including titanium (Ti), titanium nitride (TiN), tantalum (Ta), or tantalum nitride (TaN) may be disposed. The wiring structure 225 may connect the individual elements 215 to each other or connect the individual elements 215 to the conductive region 213 and the second front connection pads 232.

The second front connection pads 232 may be disposed under the second circuit layer 220. The second front connection pads 232 may include at least one of, for example, aluminum (Al), copper (Cu), nickel (Ni), tungsten (W), platinum (Pt), or gold (Au). The second front connection pads 232 may include a signal pad, a power pad, and a ground pad. The second front connection pads 232 may be disposed to face the first back connection pads 152, respectively. The second front connection pads 232 may be electrically connected to the facing first back connection pads 152 using bump structures 235.

The protective layer 231 may cover the second front surface FS2 and may have openings exposing at least a portion of each of the second front connection pads 232. The protective layer 231 may include an insulating polymer, for example, but is not limited to, Photosensitive Polyimide (PSPI). The openings may expose the second front connection pads 232, respectively.

The bump structures 235 are disposed between the first semiconductor chip 100 and the second semiconductor chip 200 and may electrically connect the first back connection pads 152 and the second front connection pads 232 facing each other. The bump structures 235 may include a pillar portion PP disposed below the second front connection pads 232 and a solder portion SP disposed below the pillar portion PP and in contact with the first back connection pads 152. The pillar portion PP may have a cylindrical or polygonal pillar shape. The pillar portion PP may include, for example, at least one of aluminum (Al), copper (Cu), nickel (Ni), tungsten (W), platinum (Pt), or gold (Au). The pillar portion PP may include a seed layer disposed on the second front connection pads 232. The solder portion SP may include, for example, tin (Sn) or an alloy (for example, Sn—Ag—Cu) including tin (Sn).

The adhesive film 400 may be disposed between the first semiconductor chip 100 and the second semiconductor chip 200. The adhesive film 400 may fill a space between the first semiconductor chip 100 and the second semiconductor chip 200 and may surround at least a portion of each of the first back connection pads 152 and the bump structures 235. The adhesive film 400 may be in contact with the side surface of each of the bump structures 235. The adhesive film 400 may be a non-conductive film (NCF), but is not limited thereto, and may include, for example, any type of polymer film capable of a thermocompression process.

The package substrate 300 may include a lower pad 312 disposed on the lower surface of the body, an upper pad 311 disposed on the upper surface of the body, and a redistribution circuit 313 electrically connecting the lower pad 312 and the upper pad 311. The redistribution circuit 313 may form an electrical path connecting the lower surface and the upper surface of the package substrate 300. The package substrate 300 may be a semiconductor package substrate including a printed circuit board (PCB), a ceramic substrate, a glass substrate, a tape wiring board, or the like. For example, when the package substrate 300 is a printed circuit board, the package substrate 300 may be in the form of an additional wiring layer being laminated on one side or both sides of a body copper-clad laminate. A solder resist layer may be formed on the lower surface and upper surface of the package substrate 300, respectively. An external connection terminal 330 connected to the lower pad 312 may be disposed below the package substrate 300. The external connection terminal 330 may be formed of a conductive material having a shape such as a ball, a pin, or the like.

Referring to FIGS. 1A and 1B, the second front connection pads 232 protrude toward the first back connection pads 152 disposed on the first back surface BS1 of the first semiconductor chip 100, thereby increasing the gap between the first semiconductor chip 100 and the second semiconductor chip 200. In other words, the structure of the second front connection pads 232 (alone or together with the first back connection pads 152) can allow the first semiconductor chip 100 and the second semiconductor chip 200 to be spaced farther apart from each other than a semiconductor package without the second front connection pads 232.

The lower surface of the second front connection pads 232 is positioned at a lower level than the lower surface of the second front surface FS2, so that the second front connection pads 232 may form a shape that protrudes (e.g., downwards) more than the second front surface FS2. The height of the second front connection pads 232 may be, for example, 5 μm or more, but is not limited thereto.

Referring to FIGS. 1A and 1B, the first back connection pads 152 may be disposed to overlap the second front connection pads 232 in the stacking direction (Z direction) of the first semiconductor chip 100 and the second semiconductor chip. The first back connection pads 152 may protrude toward the second front connection pads 232 disposed on the second front surface FS2 of the second semiconductor chip 200, thereby increasing the gap between the first semiconductor chip 100 and the second semiconductor chip 200. In other words, the structure of the first back connection pads 152 (alone or together with the second front connection pads 232) can allow the first semiconductor chip 100 and the second semiconductor chip 200 to be spaced farther apart from each other than a semiconductor package without the first back connection pads 152.

The upper surface of the first back connection pads 152 may be located at a higher level than the upper surface of the first back surface BS1. The height of the first back connection pads 152 may be, for example, about 5 μm or more, but is not limited thereto.

Referring to FIGS. 1A and 1B, in some implementations, a gap between the second front surface FS2 and the first back surface BS1 in the semiconductor package 1000a may be equal to or greater than a gap between the first front surface FS1 and the third back surface BS3. Accordingly, a vertical length of a contact surface CS(refer to FIG. 3) between the encapsulation layer 430 and the adhesive film 400 is equal to or greater than the gap between the first front surface FS1 and the third back surface BS3. The gap between the first front surface FS1 and the third back surface BS3 may be greater than a thickness of the first semiconductor chip 100. The gap between the second front surface FS2 and the first back surface BS1 may be, for example, about 61 μm to about 100 μm. For example, the combined height of the height of the bump structures 235, the height of the second front connection pads 232, and the height of the first back connection pads 152 may be about 61 μm to about 100 μm.

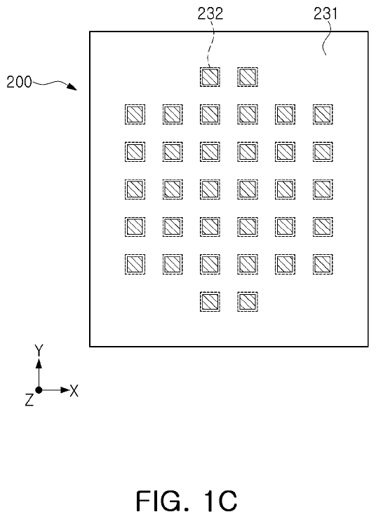

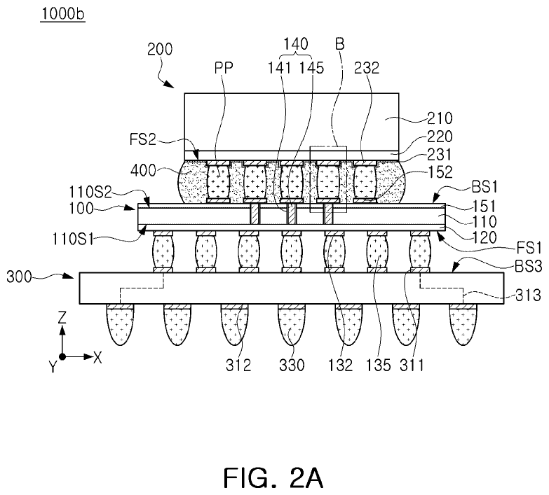

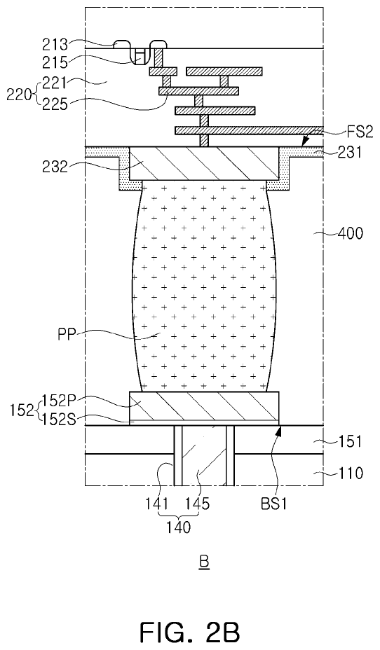

FIG. 2A is a cross-sectional view illustrating a semiconductor package 1000b according to an example implementation, and FIG. 2B is a partial enlarged view illustrating area ‘B’ of FIG. 2A.

Referring to FIGS. 2A and 2B, the semiconductor package 100b of an example implementation may have the same or similar features as those described with reference to FIGS. 1A to 1C, except that the bump structures 235 of FIG. 1A are formed as pillar portions PP.

Referring to FIGS. 2A and 2B, the second front connection pads 232 protrude toward the first back connection pads 152 disposed on the first back surface BS1 of the first semiconductor chip 100, thereby increasing the gap between the first semiconductor chip and the second semiconductor chip.

The lower surface of the second front connection pads 232 is positioned at a lower level than the lower surface of the second front surface FS2, so that the second front connection pads 232 may form a shape that protrudes (e.g., downwards) more than the second front surface FS2. The height of the second front connection pads 232 may be, for example, 5 μm or more, but is not limited thereto.

Referring to FIGS. 2A and 2B, the first back connection pads 152 may be disposed to overlap the second front connection pads 232 in the stacking direction (Z direction) of the first semiconductor chip 100 and the second semiconductor chip. The first back connection pads 152 protrude toward the second front connection pads 232 disposed on the second front surface FS2 of the second semiconductor chip 200, so that the gap between the first semiconductor chip and the second semiconductor chip may be increased.

The upper surface of the first back connection pads 152 may be positioned at a higher level than the upper surface of the first back surface BS1. The height of the first back connection pads 152 may be, for example, about 5 μm or more, but is not limited thereto.

Referring to FIGS. 2A and 2B, the gap between the second front surface FS2 and the first back surface BS1 of the semiconductor package 1000b of an example implementation may be equal to or greater than the gap between the first front surface FS1 and the third back surface BS3. The gap between the second front surface FS2 and the first back surface BS1 and the gap between the first front surface FS1 and the third back surface BS3 may be greater than the thickness of the first semiconductor chip 100.

The gap between the second front surface FS2 and the first back surface may be, for example, about 61 μm to about 100 μm. For example, the combined height of the bump structures 235, the height of the second front connection pads 232, and the height of the first back connection pads 152 may be, for example, about 61 μm to about 100 μm.

FIG. 3 is a cross-sectional view illustrating a semiconductor package 1000A according to an example implementation.

Referring to FIG. 3, the semiconductor package 1000A according to an example implementation may have the same or similar features as those described with reference to FIGS. 1A to 2B, except that it further includes an encapsulation layer 430 that seals (or encapsulates) the first semiconductor chip 100 and the second semiconductor chip 200 on the package substrate, and an encapsulation layer 440 that seals (or encapsulates) the second semiconductor and the package substrate 300. Further, according to an example implementation, the semiconductor package 1000A may be formed with bump structures 235 as pillar portions PP (see FIGS. 2A and 2B).

The encapsulation layers 430 and 440 may be formed of an insulating material such as Epoxy Mold Compound (EMC), but are not limited thereto. According to an example implementation, the encapsulation layers 430 and 440 may be formed to expose the upper surface of the second semiconductor chip 200.

The first semiconductor chip 100 may be, for example, a logic chip including a central processor (CPU), a graphics processor (GPU), a field programmable gate array (FPGA), an application processor (AP), a digital signal processor (DSP), an encryption processor, a microprocessor, a microcontroller, an analog-to-digital converter, an application-specific integrated circuit (ASIC), or the like, but is not limited thereto.

The second semiconductor chip 200 may include, but is not limited to, a memory chip such as a DRAM, an SRAM, a PRAM, an MRAM, an FeRAM, or an RRAM.

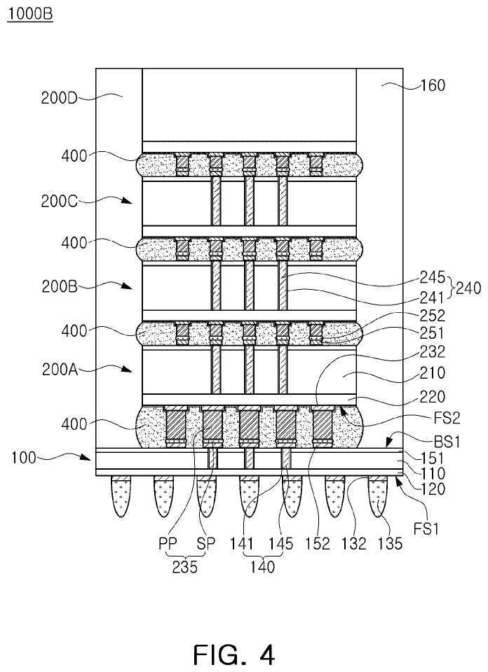

FIG. 4 is a cross-sectional view illustrating a semiconductor package 1000B according to an example implementation.

Referring to FIG. 4, in an example implementation, the semiconductor package 1000B may have the same or similar features as those described with reference to FIGS. 1A to 1C, except that a plurality of second semiconductor chips 200A, 200B, 200C and 200D are stacked on the first semiconductor chip 100. The semiconductor package 1000B may further include a molding part 160 that covers the plurality of second semiconductor chips 200A, 200B, 200C and 200D on the first semiconductor chip 100.

The molding part 160 may expose the upper surface of the uppermost second semiconductor chip 200, but is not limited thereto. The molding part 160 may be formed using, for example, EMC. The number of the plurality of second semiconductor chips 200A, 200B, 200C and 200D is not limited to that illustrated in the drawing, and may be two, three, or four or more.

The plurality of second semiconductor chips 200A, 200B, 200C and 200D may each include a second substrate 210, a second circuit layer 220, and second front connection pads 232. An adhesive film 400 may be disposed between the plurality of second semiconductor chips 200A, 200B, 200C and 200D.

The second semiconductor chips 200A, 200B and 200C, which are between the uppermost second semiconductor chip 200D and the first semiconductor chip 100, may include a second back insulating layer 251 and second back connection pads 252. The second back insulating layer 251 may electrically insulate the second back connection pads 252 from the semiconductor material forming the second substrate 210. The second back connection pads 252 may each include a seed layer 152S and a plating layer 152P. In addition, the second semiconductor chips 200A, 200B and 200C between the uppermost second semiconductor chip 200D and the first semiconductor chip 100 may include second through-electrodes 240 electrically connected to the second back connection pads 252. The second through-electrodes 240 may have the same or similar characteristics as the first through-electrodes 140 of the first semiconductor chip 100. The second through-electrodes 240 may include a second via plug 245 and a second side barrier film 241.

For example, the first semiconductor chip 100 may be a buffer chip including a plurality of logic elements and/or memory elements. Accordingly, the first semiconductor chip 100 may transmit signals to the outside from the plurality of second semiconductor chips 200A, 200B, 200C and 200D stacked thereon, and may also transmit signals and power from the outside to the plurality of second semiconductor chips 200A, 200B, 200C and 200D. The first semiconductor chip 100 may perform both a logic function and a memory function through logic elements and memory elements, but according to an example implementation, may perform only a logic function by including only logic elements. The plurality of second semiconductor chips 200A, 200B, 200C and 200D may include, for example, volatile memory chips such as DRAM and SRAM, or nonvolatile memory chips such as PRAM, MRAM, FeRAM, or RRAM. The semiconductor package 1000B of this implementation may be used in High Bandwidth Memory (HBM) products or Electro Data Processing (EDP) products.

Referring to FIG. 4, the gap between the second front surface FS2 and the first back surface BS1 of the semiconductor package 1000B of an example implementation may be greater than the thickness of the first semiconductor chip 100. In some implementations, the thickness of the first semiconductor chip 100 may be, for example, in a range of about 10 μm to about 60 μm, but is not limited thereto.

The gap between the second front surface FS2 and the first back surface may be, for example, in a range of about 61 μm to about 100 μm. For example, the combined height of the height of the bump structures 235, the height of the second front connection pads 232, and the height of the first back connection pads 152 may be, for example, in a range of about 61 μm to about 100 μm.

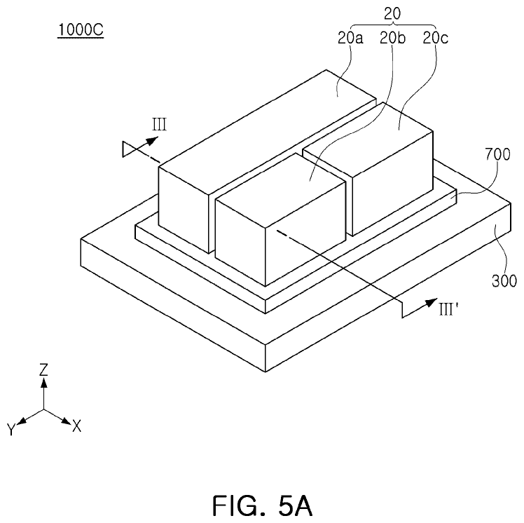

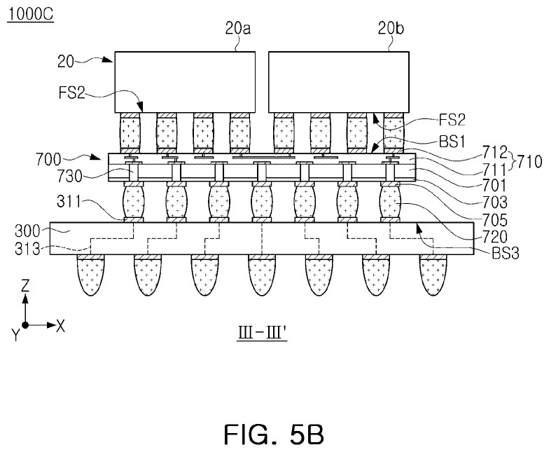

FIG. 5A is a perspective view schematically illustrating a semiconductor package 1000C according to an example implementation, and FIG. 5B is a cross-sectional view illustrating a cut section along III-III′ of FIG. 5A.

Referring to FIGS. 5A and 5B, the semiconductor package 1000C in an example implementation may include a package substrate 300, an interposer substrate 700, and at least one chip structure 20.

The chip structure 20 may include a semiconductor wafer and an integrated circuit (IC) formed of a semiconductor element such as silicon, germanium, or a compound semiconductor such as silicon carbide (SiC), gallium arsenide (GaAs), indium arsenide (InAs), and indium phosphide (InP). The chip structure 20 may be a bare semiconductor chip without a separate bump or wiring layer formed, but is not limited thereto, and may also be a packaged type semiconductor chip.

The chip structure 20 may include a logic chip such as a central processor (CPU), a graphic processor (GPU), a field programmable gate array (FPGA), an application processor (AP), a digital signal processor, an encryption processor, a microprocessor, a microcontroller, an analog-to-digital converter, an application-specific IC (ASIC), or a memory chip including a volatile memory such as a dynamic RAM (DRAM), a static RAM (SRAM), and a nonvolatile memory such as a phase change RAM (PRAM), a magnetic RAM (MRAM), a resistive RAM (RRAM), and a flash memory.

The package substrate 300 is an interposer substrate 700, a support substrate on which the chip structure 20 is mounted, and may be a semiconductor package substrate including a printed circuit board (PCB), a ceramic substrate, a glass substrate, a tape wiring substrate, or the like.

The interposer substrate 700 may include a substrate layer 701, a lower protective layer 703, a lower pad 705, an interconnection structure 710, a metal bump 720, and a through-via 730. At least one chip structure 20 may be electrically connected to each other via the interposer substrate 700.

The substrate layer 701 may be formed of, for example, any one of a silicon, an organic, a plastic, and a glass substrate. When the substrate layer 701 is a silicon substrate, the interposer substrate 700 may be referred to as a silicon interposer. Unlike what is illustrated in the drawing, when the substrate layer 701 is an organic substrate, the interposer substrate 700 may be referred to as a panel interposer.

A lower protective layer 703 may be disposed on the lower surface of the substrate layer 701, and a lower pad 705 may be disposed under the lower protective layer 703. The lower pad 705 may be connected to the through-via 730. The chip structure 20 may be electrically connected to the package substrate 300 through metal bumps 720 disposed below the lower pad 705.

The interconnection structure 710 may be disposed on the upper surface of the substrate layer 701 and may include an interlayer dielectric layer 711 and a single-layer or multi-layer wiring structure 712. When the interconnection structure 710 is formed of a multi-layer wiring structure, wiring patterns of different layers may be connected to each other through contact vias.

The through-via 730 may extend from the upper surface of the substrate layer 701 to the lower surface and extend into the substrate layer 701. The through-via 730 may extend into the interior of the interconnection structure 710 and may be electrically connected to the wirings of the interconnection structure 710. When the substrate layer 701 is silicon, the through-via 730 may be referred to as a TSV. In some example implementations, the interposer substrate 700 may only include interconnection structures therein and may not include a through-via.

The chip structure 20 may be provided as a plurality of chip structures 20a and 20b disposed on an interposer substrate 700. The plurality of chip structures 20a and 20b may be electrically connected to each other through an interconnection structure 710. For example, the plurality of chip structures 20a and 20b may include a first chip structure 20a and a second chip structure 20b. The first chip structure 20a and the second chip structure 20b may include different types of semiconductor chips. For example, the first chip structure 20a may include a logic chip such as a central processor (CPU), a graphic processor (GPU), a field programmable gate array (FPGA), a digital signal processor, an encryption processor, a microprocessor, a microcontroller, an analog-to-digital converter, an ASIC, and the like, and the second chip structure 20b may include a memory chip such as a DRAM, an SRAM, a PRAM, a ReRAM, an FeRAM, an MRAM, a flash memory. According to an example implementation, the second chip structure 20b may be provided as a high-performance memory device such as a High bandwidth memory (HBM), a Hybrid memory cube (HMC), and the like.

In some examples, the interposer substrate 700 may be used for the purpose of converting or transmitting an input electrical signal between the package substrate 300 and the plurality of chip structures 20a and 20b. In these examples, the interposer substrate 700 may not include components such as active components or passive components. In addition, according to an example implementation, the interconnection structure 710 may be disposed below the through-via 730. For example, the positional relationship between the interconnection structure 710 and the through-via 730 may be relative.

The metal bump 720 may electrically connect the interposer substrate 700 and the package substrate 300. The chip structure 20 may be electrically connected to the metal bump 720 through the wiring of the interconnection structure 710 and the through-via 730. According to an example implementation, the lower pads 705 used for power or ground may be integrated and connected together to the metal bump 720, so that the number of the lower pads 705 may be greater than the number of the metal bumps 720.

According to an example implementation, the semiconductor package 1000C may further include an inner sealant covering the chip structure 20 on the interposer substrate 700. In addition, the semiconductor package 1000C may further include an outer sealant covering the inner sealant covering the interposer substrate 700 and the inner sealant on the package substrate 300. The outer sealant and the inner sealant may be formed together and may not be distinguished. According to an example implementation, the semiconductor package 1000C may further include a heat dissipation structure covering the chip structure 20.

Referring to FIG. 5B, in some implementations, the gap between the second front surface FS2 and the first back surface BS1 of the semiconductor package 1000C may be greater than the thickness of the interposer substrate 700. In some implementations, the thickness of the interposer substrate 700 may be, for example, in the range of about 10 μm to about 60 μm, but is not limited thereto. In addition, the gap between the second front surface FS2 and the first back surface may be equal to or greater than the gap between the first front surface and the third back surface BS3. The gap between the second front surface FS2 and the first back surface may be, for example, in the range of about 61 μm to about 100 μm.

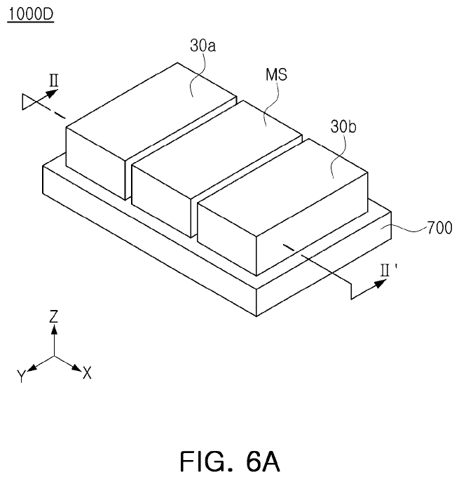

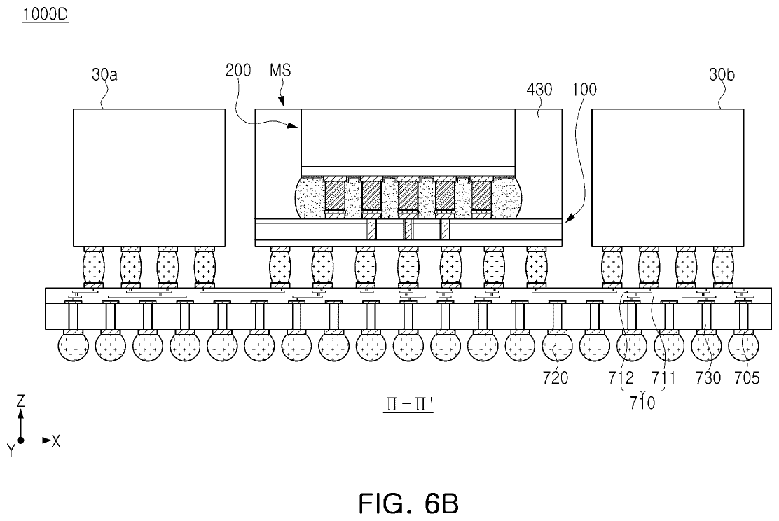

FIG. 6A is a perspective view schematically illustrating a semiconductor package 1000D according to an example implementation, and FIG. 6B is a cross-sectional view illustrating a cross-section along line II-II′ of FIG. 6A.

Referring to FIGS. 6A and 6B, the semiconductor package 1000D according to an example implementation may include an interposer substrate 700, a multi-chip structure MS, and a chip structure 30. The multi-chip structure MS may have the same or similar features as the semiconductor packages 1000B, 1000a and 1000b described with reference to FIGS. 1A to 2B and FIG. 4. For example, the multi-chip structure MS may have a structure similar to the semiconductor package 1000a illustrated in FIG. 3. For example, the first semiconductor chip 100 may be formed in an ultra-thin shape, and the thickness of the first semiconductor chip 100 may be in a range of, for example, about 10 μm to about 60 μm.

Referring to FIG. 6A, a semiconductor package 1000D according to an example implementation may have the same or similar features as those described with reference to FIGS. 5A and 5B, except that a multi-chip structure MS is mounted on an interposer substrate 700.

The interposer substrate 700 may include a substrate layer 701, a lower protective layer 703, a lower pad 705, an interconnection structure 710, a metal bump 720, and a through-via 730. The multi-chip structure MS and the chip structure 30 may be electrically connected to each other via the interposer substrate 700.

The substrate layer 701 may be formed of, for example, at least one of a silicon, organic, plastic, or glass substrate. When the substrate layer 701 is a silicon substrate, the interposer substrate 700 may be referred to as a silicon interposer. When the substrate layer 701 is an organic substrate, the interposer substrate 700 may be referred to as a panel interposer.

A lower protective layer 703 may be disposed on the lower surface of the substrate layer 701, and a lower pad 705 may be disposed under the lower protective layer 703. The lower pad 705 may be connected to a through-via 730. The multi-chip structure MS and the chip structure 30 may be electrically connected to the interposer substrate 700 through metal bumps 720 disposed under the lower pad 705.

An interconnection structure 710 may be disposed on the upper surface of the substrate layer 701. The interconnection structure 710 may include an interlayer dielectric layer 711 and a single-layer or multi-layer wiring structure 712. When the interconnection structure 710 is formed of a multilayer wiring structure, wiring patterns of different layers may be connected to each other through contact vias.

The through-via 730 may extend from the upper surface of the substrate layer 701 to the lower surface and extend into the substrate layer 701. In addition, the through-via 730 may extend into the interior of the interconnection structure 710 and be electrically connected to the wirings of the interconnection structure 710. When the substrate layer 701 is silicon, the through-via 730 may be referred to as a TSV. In some implementations, the interposer substrate 700 may include only the interconnection structure inside and may not include the through-via.

In some implementations, the interposer substrate 700 may be used for the purpose of converting or transmitting an input electrical signal between the multi-chip structure MS and the chip structure 30. In this case, the interposer substrate 700 may not include components such as active components or passive components. In addition, according to an example implementation, the interconnection structure 710 may be disposed below the through-via 730. For example, the positional relationship between the interconnection structure 710 and the through-via 730 may be relative.

The multi-chip structure MS may be electrically connected to the metal bump 720 using the wiring of the interconnection structure 710 and the through-via 730. According to an example implementation, the lower pads 705 used for power or ground may be integrated and connected together to the metal bump 720, so that the number of the lower pads 705 may be greater than the number of the metal bumps 720.

The chip structure 30 may include, but is not limited to, a central processor (CPU), a graphics processor (GPU), a field programmable gate array (FPGA), a digital signal processor (DSP), an encryption processor, a microprocessor, a microcontroller, an analog-to-digital converter, an application-specific integrated circuit (ASIC), and the like.

According to an example implementation, the semiconductor package 1000D may further include an inner sealant covering the multi-chip structure MS and the chip structure 30 on the interposer substrate 700. In addition, the semiconductor package 1000D may further include an outer sealant covering the interposer substrate 700 and the inner sealant on the package substrate 600. The outer sealant and the inner sealant may be formed together and may not be distinguished. According to an example implementation, the semiconductor package 10 may further include a heat dissipation structure covering the multi-chip structure MS and the chip structure 30.

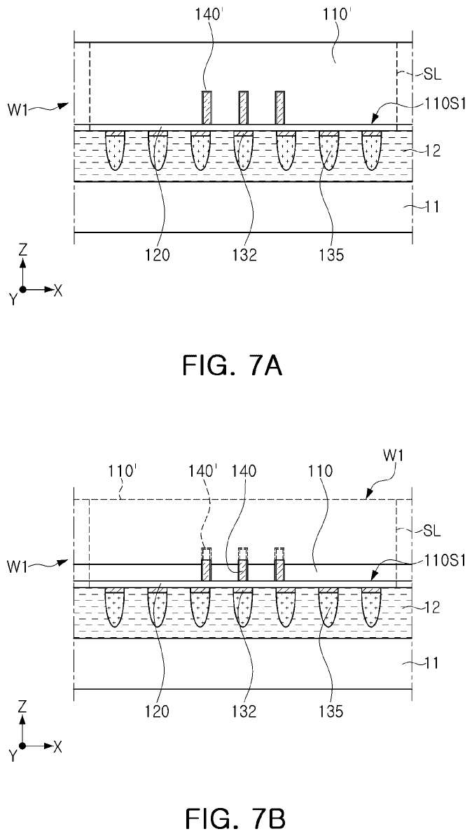

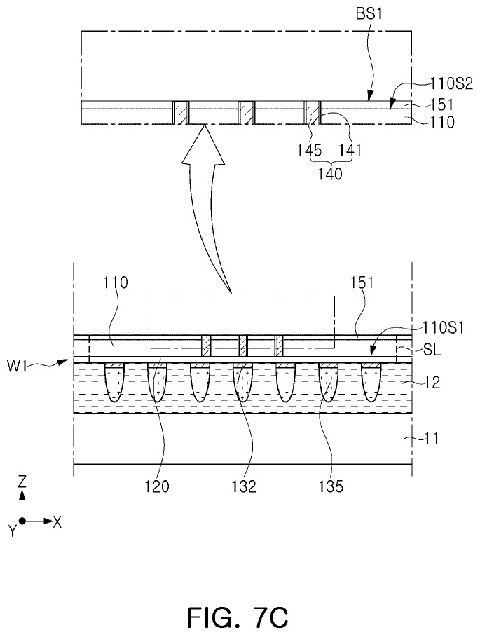

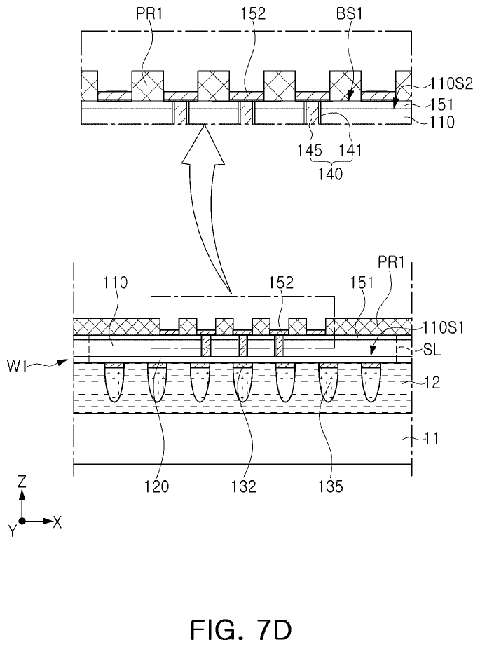

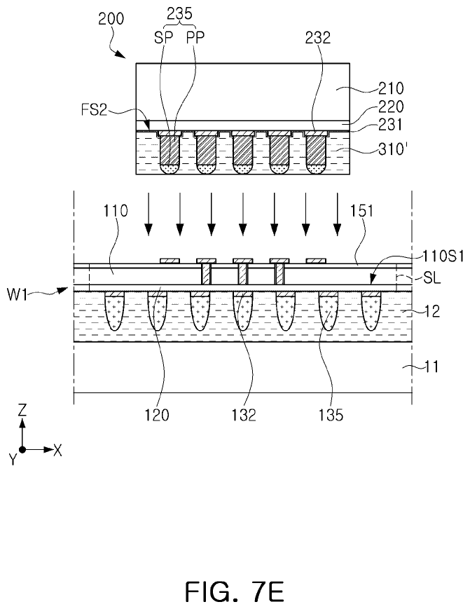

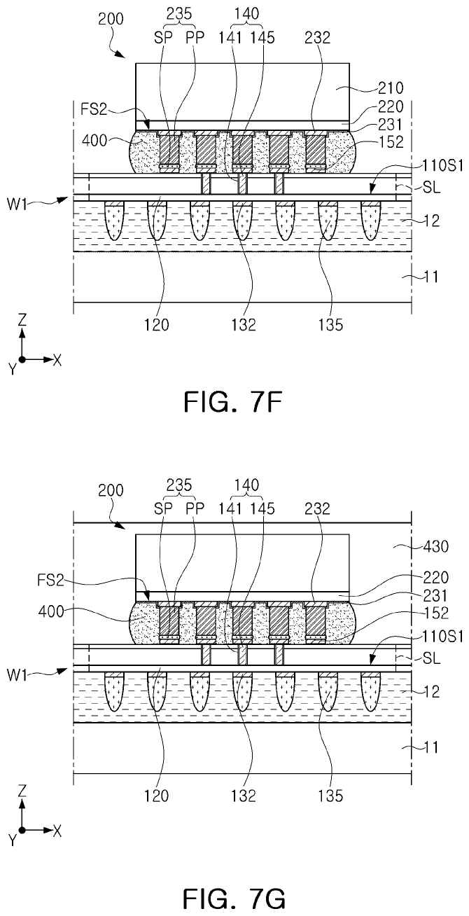

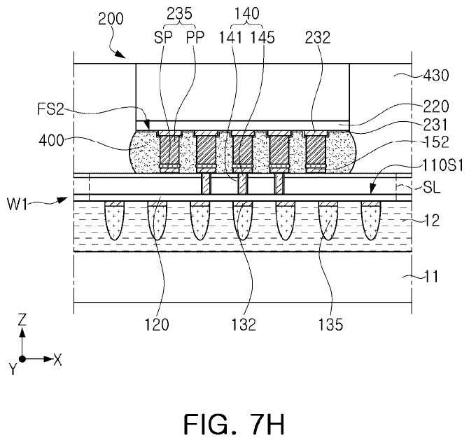

FIGS. 7A to 7H are cross-sectional views schematically illustrating a manufacturing process of a semiconductor package according to an example implementation.

Referring to FIG. 7A, a semiconductor wafer W1 may be prepared on which a circuit layer 120, first front connection pads 132, and connection bumps 135 for first semiconductor chips are formed under an active surface 110S1 of a preliminary substrate 110′. The semiconductor wafer W1 may include preliminary through-electrodes 140′ disposed in chip areas separated by scribe lines SL. A carrier substrate 11 may be disposed on a lower portion of the semiconductor wafer W1 to support and handle the semiconductor wafer W1 when performing subsequent processes. The semiconductor wafer W1 may be temporarily fixed and supported on the carrier substrate 11 by an adhesive layer 12.

Referring to FIG. 7B, a polishing process may be applied to the semiconductor wafer W1 to remove a portion of each of the preliminary substrate 110′ and/or the preliminary through-electrodes 140′. A polishing process may be applied to the upper portion of the preliminary substrate 110′ to form a first substrate 110 having a desired thickness. Accordingly, the thickness of the first semiconductor chip 100 may be, for example, in a range of about 10 μm to about 60 μm, but is not limited thereto.

The first substrate 110 may be formed to a thickness such that some of the through-electrodes 140 protrude. Some of the preliminary through-electrodes 140′ may be removed by the polishing process, and the through-electrodes 140 may be formed. The polishing process may use a chemical mechanical polishing (CMP) process, an etch-back process, or a combination thereof. For example, the preliminary substrate 110′ may be reduced to a certain thickness by performing a CMP process, and an etch-back process under appropriate conditions may be applied to sufficiently expose the through-electrodes 140.

Referring to FIG. 7C, a back insulating layer 151 surrounding the upper portion of the protruding through-electrodes 140 may be formed. The back insulating layer 151 may include silicon oxide, silicon nitride, or silicon oxynitride. The back insulating layer 151 may be formed using a PVD process or a CVD process. The back insulating layer 151 may provide a first back surface BS1 by a planarization process (for example, grinding). By the planarization process, a portion of the top of the through-electrodes 140 may also be removed. Accordingly, a portion of the through-electrodes 140 may be exposed on the first back surface BS1.

Referring to FIG. 7D, a seed material layer SD and a first plating material layer PL1 may be formed on the first back surface BS1. The seed material layer SD and the first plating material layer PL1 may be formed using a plating process, a PVD process, or a CVD process. The height of the first plating material layer PL1 may be formed to be, for example, about 5 μm or more. The seed material layer SD may include a barrier layer formed of at least one of titanium (Ti), titanium nitride (TiN), tantalum (Ta), or tantalum nitride (TaN) and a metal layer formed of at least one of copper (Cu), nickel (Ni), gold (Au), or silver (Ag). The first plating material layer PL1 may include at least one of copper (Cu), nickel (Ni), gold (Au), or silver (Ag). The first plating material layer PL1 may be formed using a patterned first photosensitive material layer PR1. The first plating material layer PL1 may correspond to the first back connection pads 152 described above. Afterwards, the first photosensitive material layer PR1 may be removed.

Referring to FIG. 7E, a second semiconductor chip 200 may be disposed on a semiconductor wafer W1. The second semiconductor chip 200 may be vacuum-absorbed by a bonding device and picked and disposed on the semiconductor wafer W1. A preliminary adhesive film 400 covering the bump structures 235 may be attached to the lower portion of the second semiconductor chip 200. The second semiconductor chip 200 may be positioned on the semiconductor wafer W1 so that the bump structures 235 are vertically aligned with the first back connection pads 152. The bump structures 235 may be formed on the second front connection pads 232. In this case, the pillar portion PP may be formed to be, for example, about 15 μm or more.

Referring to FIG. 7F, a thermal-compression bonding process may be performed to mount the second semiconductor chip 200 on the semiconductor wafer W1. An adhesive film 400 surrounding the bump structures 235 may be formed by a heat-compression process.

Referring to FIG. 7G, an encapsulation layer 430 may be formed on a semiconductor wafer W1 and a second semiconductor chip by an encapsulation process. The encapsulation layer 430 may be formed to cover the second semiconductor wafer. The present disclosure may prevent warpage and reduce cracks by increasing the height of the bump structures 235, thereby increasing the volume of the adhesive film 400 in the heat-compression process and increasing the volume of the encapsulation layer 430 in the encapsulation process.

Referring to FIG. 7H, a portion of the upper portion of the encapsulation layer 430 may be removed by using a polishing process. The encapsulation layer 430 may be formed to a desired thickness by applying a polishing process. The encapsulation layer 430 may be formed with a thickness that allows a portion of the second semiconductor chip 200 to protrude. The polishing process may use a chemical mechanical polishing (CMP) process, an etch-back process, or a combination thereof.

As set forth above, according to an example implementation, a semiconductor package with improved reliability and yield may be provided by increasing the gap between semiconductor chips and thereby increasing the volume of an adhesive film and an encapsulation layer.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been illustrated and described above, it will be apparent to those skilled in the art that modifications and variations could be made without departing from the scope of the present disclosure as defined by the appended claims.

What is claimed is:

1. A semiconductor package comprising:
a first semiconductor chip having a first front surface and a first back surface, the first semiconductor chip including:
first front connection pads on the first front surface,
first back connection pads on the first back surface, and
through-electrodes electrically connecting the first front connection pads to the first back connection pads;
a second semiconductor chip having a second front surface facing the first back surface and including second front connection pads on the second front surface;
a substrate having a third back surface facing the first front surface and including upper pads and lower pads opposite to the upper pads;
first bump structures between the first semiconductor chip and the second semiconductor chip and electrically connecting the first back connection pads and the second front connection pads;
second bump structures between the first semiconductor chip and the substrate and electrically connecting the upper pads of the substrate and the first front connection pads of the first semiconductor chip; and
connection bumps below the lower pad of the substrate,
wherein a first gap between the second front surface and the first back surface is a same as or greater than a second gap between the first front surface and the third back surface, and the second gap is greater than a thickness of the first semiconductor chip.

2. The semiconductor package of claim 1, wherein the first bump structures include a solder ball connecting the second front connection pads and the first back connection pads.

3. The semiconductor package of claim 1, wherein the first bump structures include:
a pillar bump contacting the second front connection pads,
a solder ball connecting the pillar bump and the first back connection pads, and
a barrier film covering a side surface of the pillar bump.

4. The semiconductor package of claim 3, wherein upper surfaces of the first back connection pads are located at a higher level than an upper surface of the first back surface.

5. The semiconductor package of claim 3, wherein a height of at least one of the first back connection pads that protrudes farther than an upper surface of the first back surface is 5 μm or more.

6. The semiconductor package of claim 3, wherein a height of the pillar bump is 15 μm or more.

7. The semiconductor package of claim 1, comprising an adhesive film between the first semiconductor chip and the second semiconductor chip, the adhesive film surrounding the first back connection pads and respective portions of the first bump structures.

8. The semiconductor package of claim 1, comprising an encapsulation layer on the first semiconductor chip, the encapsulation layer covering the first semiconductor chip.

9. The semiconductor package of claim 1, wherein the first gap between the second front surface and the first back surface is in a range of 61 μm to 100 μm.

10. The semiconductor package of claim 1, wherein a thickness of the first semiconductor chip is in a range of 10 μm to 60 μm.

11. The semiconductor package of claim 1, wherein a thickness of the second semiconductor chip is in a range of 300 μm to 750 μm.

12. The semiconductor package of claim 1, wherein the first semiconductor chip includes an interconnection structure connecting the through-electrodes and the first back connection pads, and
wherein the second semiconductor chip provides a plurality of chip structures on the first semiconductor chip,
wherein the plurality of chip structures are connected to each other through the interconnection structure.

13. The semiconductor package of claim 12, wherein the plurality of chip structures include a first chip structure and a second chip structure,
wherein the first chip structure includes a logic chip, and
wherein the second chip structure includes a memory chip.

14. The semiconductor package of claim 1, wherein the substrate includes:
through-vias electrically connecting the upper pads and the lower pads, and
a second interconnection structure electrically connecting the through-vias and the upper pads.

15. The semiconductor package of claim 14, comprising a plurality of chip structures on the substrate and including connection pads,
wherein the plurality of chip structures and the first semiconductor chip are connected to each other through the second interconnection structure.

16. A semiconductor package comprising:
a first semiconductor chip having a first front surface and a first back surface, the first semiconductor chip including:
first front connection pads on the first front surface,
first back connection pads on the first back surface, and
through-electrodes electrically connecting the first front connection pads to the first back connection pads;
a second semiconductor chip having a second front surface facing the first back surface and including second front connection pads on the second front surface;
a substrate having a third back surface facing the first front surface and including upper pads and lower pads opposite to the upper pads;
first bump structures between the first semiconductor chip and the second semiconductor chip and electrically connecting the first back connection pads and the second front connection pads;
second bump structures between the first semiconductor chip and the substrate and electrically connecting the upper pads of the substrate and the first front connection pads of the first semiconductor chip; and
connection bumps below the substrate,
wherein a thickness of the first semiconductor chip is in a range of 10 μm to 60 μm, and
wherein a first gap between the second front surface and the first back surface is a same as or greater than a second gap between the first front surface and the third back surface.

17. The semiconductor package of claim 16, wherein a ratio of a thickness of the second semiconductor chip and the thickness of the first semiconductor chip is 8.4 or more.

18. The semiconductor package of claim 16, comprising:
an adhesive film between the first semiconductor chip and the second semiconductor chip, the adhesive film surrounding the first back connection pads and a portion of each of the first bump structures, and
an encapsulation layer on the first semiconductor chip, the encapsulation layer covering the first semiconductor chip.

19. A semiconductor package comprising:
a first semiconductor chip having a first front surface and a first back surface, the first semiconductor chip including:
first front connection pads on the first front surface,
first back connection pads on the first back surface, and
through-electrodes electrically connecting the first front connection pads to the first back connection pads;
a second semiconductor chip having a second front surface facing the first back surface, and including second front connection pads on the second front surface;
a substrate having a third back surface facing the first front surface and including upper pads and lower pads opposite to the upper pads;
first bump structures between the first semiconductor chip and the second semiconductor chip, and electrically connecting the first back connection pads and the second front connection pads;
second bump structures between the first semiconductor chip and the substrate, and electrically connecting the upper pads of the substrate and the first front connection pads of the first semiconductor chip;
connection bumps below the substrate;
an adhesive film between the first semiconductor chip and the second semiconductor chip, the adhesive film surrounding the first back connection pads and a portion of each of the first bump structures; and
an encapsulation layer on the first semiconductor chip and surrounding a side surface of the adhesive film and a side surface of the second semiconductor chip,
wherein a vertical length of a contact surface between the encapsulation layer and the adhesive film is a same as or greater than a gap between the first front surface and the third back surface, and the gap is greater than a thickness of the first semiconductor chip.

20. The semiconductor package of claim 19, wherein the vertical length of the contact surface between the encapsulation layer and the adhesive film is in a range of 61 μm to 100 μm.
